(19) United States
(12) Patent Application Publication
(10) Pub. No.: US 2008/0107975 A1
(43) Pub. Date: May 8, 2008

(54) Method of Correcting Photomask Defect

(76) Inventors: Osamu Takaoka, Chiba-shi (JP); Junichi Tashiro, Chiba-shi (JP)

Correspondence Address: BRINKS HOFER GILSON & LIONE, P.O. BOX 10395, CHICAGO, IL, 60610, US

(21) Appl. No.: 11/925,039

(22) Filed: Oct. 26, 2007

(30) Foreign Application Priority Data
Oct. 31, 2006 (JP) JP2006-295836
Aug. 28, 2007 (JP) JP2007-220474

(51) Int. Cl. G03F 1/00

(52) U.S. Cl. 430/5

(57) ABSTRACT

After making an electrical continuity in the isolated pattern by a metal deposition film by a CVD of the electron beam or the helium ion beam generating from the gas field ion source, the defect is corrected and, after the correction, the metal deposition film is physically removed by an AFM scratch working probe. A worked waste generated by the AFM scratch working is removed by a washing.

### RELATED APPLICATIONS

This application claims priority under 35 U.S.C. §119 to Japanese Patent Application Nos. JP2006-295836 filed Oct. 31, 2006, and JP2007-220474 filed Aug. 28, 2007, the entire content of which is hereby incorporated by reference.

### BACKGROUND OF THE INVENTION

The present invention is one relating to a method of correcting a defect in an isolated pattern of a photomask, in which there is used an electron beam or a helium ion beam from a gas field ion source.

A lithography responds to a demand for fining a semiconductor integrated circuit by shortening a wavelength of a light source of a reduced projection exposure apparatus and increasing an NA. A defect correction of the photomask, in which there is demanded the fact that there is no defect in an original form of a transcription in the reduced projection exposure apparatus, is performed hitherto by using a laser or a focused ion beam. However, with the laser, a resolving power is insufficient and thus the defect of a fine pattern in a most tip cannot be corrected and, with the focused ion beam, an imaging damage (decrease in transmittance) of a glass part, which is due to an implantation of gallium used as a primary beam, becomes an issue following upon the shortening of the wavelength of the light source of the reduced projection exposure apparatus. Whereupon, there is demanded a defect correction technique which can correct the defect of the fine pattern, and in which there is no imaging damage. From the background like this, recently there is developed an electron beam photomask defect correction apparatus in which an opaque defect is corrected by a gas assist etching by the electron beam, and a clear defect is corrected by depositing a shading film by an electron beam CVD (K. Edinger, H. Becht, J. Bihr, V. Boegli, M. Budach, T. Hofmann, H. P. Coops, P. Kuschnerus, J. Oster, P. Spies, and B. Weyrauch, J. Vac. Sci. Technol. B22 2902-2906 (2004)). Further, there is known the fact that the imaging damage is not exerted even if a rare gas ion beam is used, besides the electron beam. Since an imaging and a working are performed by the electron beam, there occurs no fact that the transmittance decreases at a high transmittance and by the implantation of gallium. In addition to the electron beam photomask defect correction apparatus, there is also developed an apparatus removing the defect by a mechanical working by applying an atomic force microscope (AFM) technique (Y. Morikawa, H. Kokubo, M. Nishiguchi, N. Hayashi, R. White, R. Bozak, and L. Terrill, Proc. of SPIE 5130 520-527 (2003)).

However, since the photomask is one in which a metal film is deposited on a glass in order to shield a light, in a case where an area of a metal film pattern is small, a charge-up generates by an excessive electric charge in an electron beam irradiation. If the charge-up occurs, there are a decrease in a quality of a secondary electron image, and an issue that a drift of the electron beam generates, thereby decreasing a working accuracy. Further, hitherto, although a fine hole or protrusion is made by the electron beam and it is utilized as a drift marker, it is becoming difficult to provide the hole or protrusion like this in order to fine the pattern and shorten an exposure wavelength. If a longitudinal and lateral pattern exists in a working window, a drift correction can be performed by using an edge of the pattern as the drift marker. However, also a case where a suitable longitudinal and lateral pattern does not exist in the working window is frequent, so that there is demanded the drift marker capable of being used in many ways.

On the other hand, in the electron beam CVD, there is known the fact that, besides the shading film for correcting the clear defect, an electrically conductive film can be deposited in a desired position if hexacarbonyl tungsten (W(CO)₆) or the like is used as a deposition raw material gas (K. T. Kohlmann-von Platen, J. Chlebek, M. Weiss, H. Oertel, and W. H. Brunger, J. Vac. Sci. Technol. B11 2219-2223 (1993)).

An object of the present invention is to overcome the problems resulting from the charge-up when correcting the defect of the isolated pattern by using the electron beam or the helium ion beam obtained from the gas field ion source.

### SUMMARY OF THE INVENTION

After a conductor wire electrically connecting an isolated pattern having an opaque or clear defect and a non-isolated pattern is made by a metal deposition film deposited by a CVD of an electron beam or a helium ion beam generating from a gas field ion source, the opaque or clear defect is recognized by the electron beam or the helium ion beam generating from the gas field ion source, and the defect is corrected by removing (in a case of the opaque defect) it or depositing (in a case of the clear defect) a shading film by the electron beam or the helium ion beam generating from the gas field ion source. After the correction, the metal deposition film is removed by an AFM scratch working. A worked waste generated by the AFM scratch working is removed by a washing.

The metal deposition film is deposited in an X-direction and a Y-direction as the conductor wire to the isolated pattern by the CVD using the electron beam or the helium ion beam generating from the gas field ion source, the conductor wire made of the metal deposition film in the X-direction and the Y-direction is used as a marker of a drift correction in a defect correction and, after the correction, the metal deposition film is removed by the AFM scratch working.

Since it is possible to avoid the charge-up by an excessive electric charge accumulation if also the isolated pattern can be connected to other pattern by the conductor wire, it is possible to perform a working of a high accuracy, in which an image is good in its quality and there is no drift, by a charge, of the electron beam or the helium ion beam generating from the gas field ion source. Further, the gas assist etching of the electron beam or the helium ion beam generating from the gas field ion source has a material dependency and, although there exists also a material not capable of being shaved, any material can be shaved off if the AFM scratch working is used.

Even in the case where the suitable longitudinal and lateral pattern for the drift correction does not exist in the working window, it is possible to use the metal deposition film provided by the CVD, in which the electron beam or the helium ion beam generating from the gas field ion source is used, as the drift marker. Since the charge-up can be avoided by the fact that the metal deposition film becomes the conductor wire, it is possible to take the image, in which there is no drift by the charge as well and whose quality is good, of the drift marker. By the drift correction using the image whose quality is good, since the drift in a working position of the electron beam or the helium ion beam generating from the gas field ion source can be highly accurately corrected, it is possible to perform a highly accurate working.

As to the deposition film of the electron beam or the helium ion beam generating from the gas field ion source, when it is removed by an AFM, there scarcely exists a damage to a ground glass substrate while differing from a deposition film in which there is used a focused ion beam obtained from a liquid metal ion source, and also there is no fact that an optical property of the photomask is deteriorated.

### BRIEF DESCRIPTION OF THE DRAWINGS

FIGS. 1A-1D are schematic sectional views of a photomask, for explaining a case correcting an opaque defect of an isolated pattern by the present invention.

FIGS. 2A-2D are schematic sectional views of the photomask, for explaining a case correcting a clear defect of the isolated pattern by the present invention.

FIGS. 3A-3D are top views of the photomask, for explaining a case where a metal deposition film is used as a drift marker.

### DETAILED DESCRIPTION OF THE PREFERRED EMBODIMENT

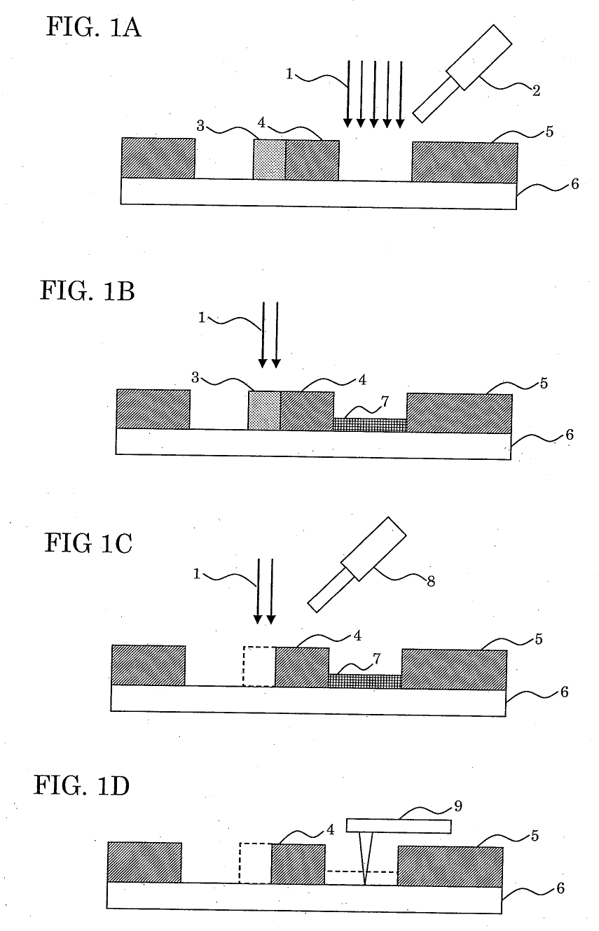

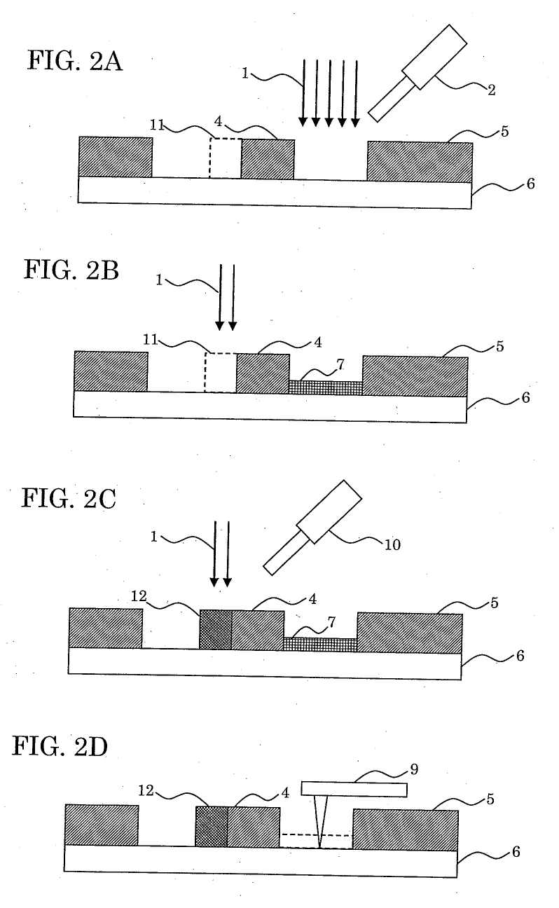

Hereunder, about an embodiment of the present invention, there is detailedly explained by using the drawings. FIGS. 1A-1D are schematic sectional views of the photomask, for explaining a case correcting the opaque defect of the isolated pattern by the present invention, and FIGS. 2A-2D are schematic sectional views of the photomask, for explaining a case correcting the clear defect of the isolated pattern by the present invention.

The photomask having the defect is introduced to an electron beam fine working apparatus having a shading film raw material gas introduction system 10, a metal deposition film raw material gas introduction system 2, and a gas introduction system 8 for a gas assist etching, and an XY stage is moved such that a defect position previously found by a defect inspection device enters into a visual field.

A region including the defect is observed and, in a case where an isolated defect or an isolated pattern 4 on a glass substrate 6, in which the defect exists, undergoes an influence of the charge-up, there is made a conductor wire 7 connecting a normal pattern 5 and the isolated pattern 4 by a metal deposition film by an electron beam CVD by selectively irradiating an electron beam 1 only to a portion becoming the conductor wire while flowing a metal deposition film raw material gas such as hexacarbonyl tungsten from the gas introduction system 2 (FIG. 1A and FIG. 2A).

By suitably selecting the metal deposition film raw material gas, the conductor wire can be made not only by a tungsten system but also by a platinum system. After making the conductor wire, an image is taken again under a state in which there is no charge-up, and a defect region to be corrected is recognized by being compared with the normal pattern having no defect by a pattern matching or the like (FIG. 1B and FIG. 2B).

In a case of the opaque defect, the opaque defect is corrected by removing an excessive portion by selectively irradiating the electron beam 1 only to an opaque defect region 3 while flowing a gas for the gas assist etching, such as xenon fluoride, from the gas introduction system 8 (FIG. 1C).

In a case of the clear defect, the clear defect is corrected by forming a shading film 12 by selectively irradiating the electron beam 1 only to a clear defect region 11 while flowing a shading film raw material gas such as naphthalene or phenanthrene from the gas introduction system 10 (FIG. 2C).

After the defect correction, the conductor wire 7 made of the metal deposition film made for an electrical continuation is physically removed by a working probe 9 of an AFM fine working apparatus (FIG. 1D and FIG. 2D).

The worked waste generated by the AFM scratch working is removed by the washing by a wet washing or a dry ice cleaner.

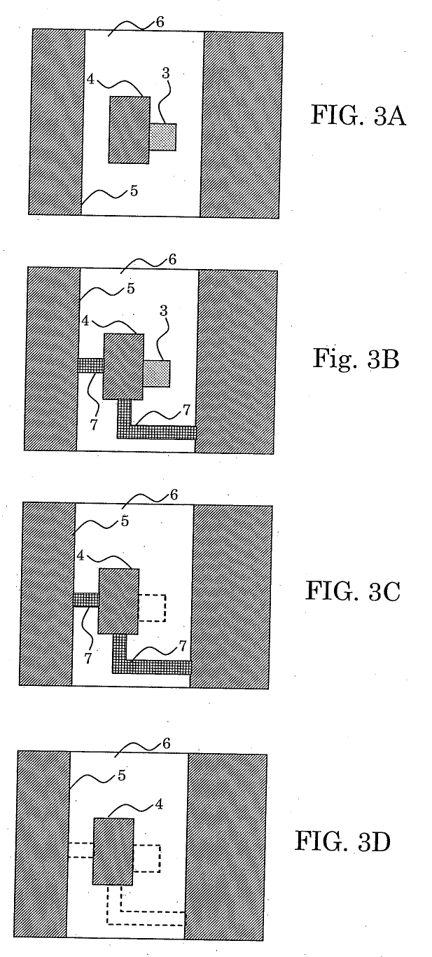

FIGS. 3A-3D are top views of the photomask, for explaining a case where the metal deposition film is used as the drift marker in the present invention.

The isolated pattern 4 has the opaque defect 3 (FIG. 3A). In the case where the suitable longitudinal and lateral pattern for the drift correction does not exist in the working window, the metal deposition film 7 deposited for the electrical continuation by using the electron beam CVD is used as a maker for the drift correction.

The metal deposition film 7 is deposited in the X-direction and the Y-direction to the isolated defect or the isolated pattern including the defect by the electron beam CVD, thereby making it the conductor wire (FIG. 3B).

The metal deposition film 7 is constituted by a line directed in the X-direction and a line directed in the Y-direction, which are continuously connected. The clear defect or the opaque defect 3 is corrected by the same method as the above by extracting the metal deposition film conductor wire 7 in the X-direction and the Y-direction by utilizing the pattern matching or the like, and using it as the marker of the drift correction at a working time (FIG. 3C), a case of the clear defect correction is not displayed).

After the correction, similarly to the above, the metal deposition film 7 used for the maker of the drift correction is physically removed by the working probe 9 of the AFM fine working apparatus (FIG. 3D). The worked waste generated by the AFM scratch working is removed by the washing by the wet washing or the dry ice cleaner.

Up to here, although there is explained about the method of correcting the photomask defect, in which the electron beam fine working apparatus is used, even if there is used a fine working apparatus possessing the gas field ion source instead of the electron beam, it is possible to overcome the issue resulting from the charge-up when correcting the defect of the isolated pattern. In this case, in the drawings, the electron beam 1 is replaced with an ion beam 1 from the gas field ion source.

There is explained about the fine working apparatus possessing the gas field ion source. As to the gas field ion source, since a source size can be made 1 nm or smaller and an energy spread of anion beam 1 eV or less as well, a beam diameter can be reduced to 1 nm or smaller. Like this, since the beam diameter can be made small, it is possible to apply a fine working (etching, deposition) to a sample.

In an operation principle of the gas field ion source, a trace gas (e.g., helium gas) is supplied from a gas supply source to an emitter cooled by a refrigerant such as liquid nitrogen and sharpened at an atomic level. If a voltage is applied between the emitter and a leader electrode, a very large electric field is formed in a keenly sharpened emitter tip, and helium atoms attracted to the emitter are ionized and released as an ion beam. Since the tip of the emitter has a very sharp shape and the helium ions fly out from this tip, an energy distribution width of the ion beam released from the gas field ion source is very narrow, and it is possible to obtain the ion beam whose diameter is small and whose brightness is high in comparison with a conventional plasma type gas ion source or liquid metal ion source.

Even if there is used the fine working apparatus possessing the above-mentioned gas field ion source instead of the electron beam, since the helium gas ion is small in its sputtering effect in comparison with gallium ion, the gas assist etching using an etching gas has the material dependency, and any material can be shaved off if the AFM scratch working is used. Further, since also the metal deposition film manufacture by using the ion beam generating from the gas field ion source can be used as the drift marker, the drift can be highly accurately corrected at, and it is possible to perform a highly accurate working. Further, as to the deposition film manufactured by the helium ion beam generating from the gas field ion source, when it is removed by the AFM, there scarcely exists the damage to the ground glass substrate while differing from the deposition film in which there is used the focused ion beam obtained from the liquid metal ion source, and also there is no fact that the optical property of the photomask is deteriorated.

Like the above, even if there is used the fine working apparatus possessing the gas field ion source instead of the electron beam, since it is possible to avoid the charge-up by the excessive electric charge accumulation if also the isolated pattern can be connected to other pattern by the conductor wire, it is possible to perform the working of the high accuracy, in which the image is good in its quality and there is no drift, by the charge, of the electron beam or the ion beam generating from the gas field ion source.

What is claimed is:

1. A method of correcting a photomask defect, characterized in that, after a metal deposition film electrically connecting between an isolated pattern having an opaque or clear defect and a non-isolated pattern is provided by a CVD of an electron beam or a helium ion beam generating from a gas field ion source, the opaque or clear defect is corrected by using the electron beam or the helium ion beam generating from the gas field ion source and, after the correction, the metal deposition film is removed by an AFM scratch working.

2. A method of correcting a photomask defect according to claim 1, characterized in that the metal deposition film is used as a marker of a drift correction.

3. A method of correcting a photomask defect according to claim 1, characterized in that the metal deposition film is a matter containing tungsten.

4. A method of correcting a photomask defect according to claim 1, characterized in that the metal deposition film is a matter containing platinum.
